(19) United States
(12) Patent Application Publication
(10) Pub. No.: US 2024/0284771 A1
(43) Pub. Date: Aug. 22, 2024

(54) DISPLAY SUBSTRATE, INSPECTION METHOD THEREOF, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yuanjie XU, Beijing (CN); Yue LONG, Beijing (CN); Cong LIU, Beijing (CN); Binyan WANG, Beijing (CN); Zhuoran YAN, Beijing (CN); Shuang LI, Beijing (CN)

(21) Appl. No.: 18/041,202

(22) PCT Filed: Feb. 25, 2022
(86) PCT No.: PCT/CN2022/077967

§ 371 Date: Feb. 9, 2023

(51) Int. Cl. H10K 59/88; G09G 3/3233; H10K 59/131

(52) U.S. Cl. CPC H10K 59/88; H10K 59/131; G09G 3/3233; G09G 2300/0426; G09G 2300/0819; G09G 2300/0842; G09G 2300/0861; G09G 2310/08

(57) ABSTRACT

A display substrate, inspection method thereof, and display device are provided. The display substrate includes a base substrate including a first region and a second region. The second region includes multiple driving circuitries, which include multiple normal driving circuitries and multiple dummy driving circuitries; the dummy driving circuitries each include a dummy driving transistor, and some of the normal driving circuitries are for driving an anode pattern in the first region; the multiple driving circuitries are divided into multiple driving circuitry columns, which are sequentially arranged in a nested manner and all surround the first region. The display substrate further includes multiple signal lead-out lines and multiple test pads, and the signal lead-out lines are coupled to corresponding test pads; in at least some of the driving circuitry columns, electrodes of a target dummy driving transistor in a target dummy driving circuitry are coupled to corresponding signal lead-out lines, respectively.

### TECHNICAL FIELD

The present disclosure relates to the field of display technology, in particular to a display substrate, an inspection method thereof, and a display device.

### BACKGROUND

In an organic light-emitting diode (OLED) display product, in order to achieve narrow bezel and full-screen display, a camera is generally arranged in an under-screen camera region of the display product. The under-screen camera region is generally provided with only light-emitting elements, and driving circuitries for driving the light-emitting elements are arranged at the periphery of the under-screen camera region.

### SUMMARY

The present disclosure provides a display substrate, an inspection method thereof and a display device.

In a first aspect, the present disclosure provides a display substrate, which includes a base substrate including a first region and a second region. The second region includes a plurality of driving circuitries, the plurality of driving circuitries include a plurality of normal driving circuitries and a plurality of dummy driving circuitries; each of the normal driving circuitries includes a normal driving transistor, each of the dummy driving circuitries includes a dummy driving transistor, and some of the normal driving circuitries are for driving an anode pattern in the first region; and the plurality of driving circuitries are divided into a plurality of driving circuitry columns, all of the driving circuitry columns surround the first region, and each of the driving circuitry columns surrounds a driving circuitry column located between the each of the driving circuitry columns and the first region. The display substrate further includes a plurality of signal lead-out lines and a plurality of test pads, and the signal lead-out lines each are coupled to a corresponding test pad; and in at least some of the driving circuitry columns, at least one electrode of a target dummy driving transistor in a target dummy driving circuitry is coupled to at least one signal lead-out line.

In a possible embodiment of the present disclosure, the plurality of driving circuitries are divided into a plurality of driving circuitry rows, each of the driving circuitry rows includes at least one of the driving circuitries that is arranged in a first direction; and the display substrate further includes a plurality of signal lines, at least a part of each signal line extends along the first direction, and the signal lines are coupled to driving circuitries in corresponding driving circuitry rows respectively; and a signal line correspondingly coupled to the driving circuitry row to which the target dummy driving transistor belongs is reused as the signal lead-out line coupled to the target dummy driving transistor.

In a possible embodiment of the present disclosure, the plurality of signal lines include a plurality of gate lines, a plurality of light-emitting control lines and a plurality of reset lines; each of the driving circuitry rows is coupled to a corresponding gate line, a corresponding light-emitting control line and a corresponding reset line; and at least one of the gate line, the light-emitting control line or the reset line correspondingly coupled to the driving circuitry row to which the target dummy driving transistor belongs is reused as the signal lead-out line coupled to the target dummy driving transistor.

In a possible embodiment of the present disclosure, the reset line correspondingly coupled to the driving circuitry row to which the target dummy driving transistor belongs is reused as the signal lead-out line coupled to a gate electrode of the target dummy driving transistor; the gate line correspondingly coupled to the driving circuitry row to which the target dummy driving transistor belongs is reused as the signal lead-out line coupled to a first electrode of the target dummy driving transistor; and the light-emitting control line correspondingly coupled to the driving circuitry row to which the target dummy driving transistor belongs is reused as the signal lead-out line coupled to a second electrode of the target dummy driving transistor.

In a possible embodiment of the present disclosure, the reset line correspondingly coupled to the driving circuitry row to which the target dummy driving transistor belongs and the gate electrode of the target dummy driving transistor are formed into an integral structure.

In a possible embodiment of the present disclosure, the target dummy driving circuitry includes a first electrically conductive connection portion; and the gate line correspondingly coupled to the driving circuitry row to which the target dummy driving transistor belongs is coupled to the first electrode of the target dummy driving transistor through the first electrically conductive connection portion.

In a possible embodiment of the present disclosure, the target dummy driving circuitry includes a second electrically conductive connection portion; and the light-emitting control line correspondingly coupled to the driving circuitry row to which the target dummy driving transistor belongs is coupled to the second electrode of the target dummy driving transistor through the second electrically conductive connection portion.

In a possible embodiment of the present disclosure, the display substrate includes a first source-drain metal layer, and the first electrically conductive connection portion and/or the second electrically conductive connection portion is made of the first source-drain metal layer.

In a possible embodiment of the present disclosure, the at least some of the driving circuitry columns include an odd quantity of driving circuitry columns or an even quantity of driving circuitry columns.

In a possible embodiment of the present disclosure, adjacent driving circuitry columns in the at least some of the driving circuitry columns are spaced apart by at least one other driving circuitry column, and the other driving circuitry column does not include the target dummy driving circuitry.

In a possible embodiment of the present disclosure, the display substrate further includes an active layer, a first gate insulation layer, a first gate metal layer, a second gate insulation layer, a second gate metal layer, an interlayer insulation layer and a first source-drain metal layer stacked sequentially in a direction away from the base substrate; and the first region further includes a compensation structure, the compensation structure is made of at least one of the active layer, the first gate insulation layer, the first gate metal layer, the second gate insulation layer, the second gate metal layer, the interlayer insulation layer or the first source-drain metal layer.

In a possible embodiment of the present disclosure, the compensation structure includes compensation patterns uniformly distributed throughout the first region.

In a possible embodiment of the present disclosure, the first region includes a plurality of anode patterns, the compensation structure includes a plurality of first compensation patterns and a plurality of second compensation patterns; an orthogonal projection of the first compensation pattern onto the base substrate at least partially overlaps an orthogonal projection of a corresponding anode pattern onto the base substrate, an orthogonal projection of the second compensation pattern onto the base substrate at least partially overlaps the orthogonal projection of the corresponding anode pattern onto the base substrate; and the first compensation patterns are arranged at a layer different from the second compensation patterns.

In a possible embodiment of the present disclosure, the first compensation pattern includes a plurality of independent sub-compensation patterns, and an orthogonal projection of the sub-compensation pattern onto the base substrate at least partially overlaps the orthogonal projection of the corresponding anode pattern onto the base substrate.

In a possible embodiment of the present disclosure, the second compensation pattern includes a plurality of via holes, and an orthogonal projection of the via hole onto the base substrate at least partially overlaps the orthogonal projection of the corresponding anode pattern onto the base substrate.

In a possible embodiment of the present disclosure, an orthogonal projection of the via holes in the second compensation pattern corresponding to the anode pattern onto the base substrate is covered by an orthogonal projection of the sub-compensation patterns corresponding to the anode pattern onto the base substrate.

In a possible embodiment of the present disclosure, the first compensation patterns are made of the active layer, and the second compensation patterns are made of the interlayer insulation layer.

In a possible embodiment of the present disclosure, the plurality of anode patterns include a plurality of first anode patterns, a plurality of second anode patterns and a plurality of third anode patterns, and colors of sub-pixels corresponding to the first anode pattern, the second anode pattern and the third anode pattern are different; and at least two of the first anode pattern, the second anode pattern and the third anode pattern correspond to the first compensation patterns with different areas, and correspond to the second compensation patterns with different areas.

In a possible embodiment of the present disclosure, two of the first anode pattern, the second anode pattern and the third anode pattern correspond to the first compensation patterns with a same area, and correspond to the second compensation patterns with a same area.

In a possible embodiment of the present disclosure, the first anode pattern corresponds to a blue sub-pixel, the second anode pattern corresponds to a red sub-pixel, and the third anode pattern corresponds to a green sub-pixel; an area of the first compensation pattern corresponding to the first anode pattern is greater than an area of the first compensation pattern corresponding to the second anode pattern; and a quantity of the via holes corresponding to the first anode pattern is greater than a quantity of the via holes corresponding to the second anode pattern.

In a possible embodiment of the present disclosure, the compensation pattern is made of one of the active layer, the first gate insulation layer, the first gate metal layer, the second gate insulation layer, the second gate metal layer, the interlayer insulation layer and the first source-drain metal layer.

In a possible embodiment of the present disclosure, the compensation structure includes a plurality of compensation driving circuitries, and a circuit structure of each of the compensation driving circuitries is the same as a circuit structure of the dummy driving circuitry or a circuit structure of the normal driving circuitry.

In a possible embodiment of the present disclosure, the plurality of compensation driving circuitries are divided into at least two compensation driving circuitry columns, the at least two compensation driving circuitry columns are sequentially arranged in a nested manner, and the at least two compensation driving circuitry columns are located at an edge of the first region.

In a possible embodiment of the present disclosure, the plurality of test pads are arranged in a bezel region of the display substrate.

In a possible embodiment of the present disclosure, the first region includes an under-screen camera region, and the second region includes a transition region.

Based on the technical solution of the above-mentioned display substrate, the present disclosure further provides in a second aspect a display device including the above-mentioned display substrate.

Based on the technical solution of the above-mentioned display substrate, the present disclosure further provides in a third aspect an inspection method of a display substrate, for inspecting the above-mentioned display substrate. The method includes: inputting corresponding test signals to test pads in the display substrate; obtaining signals of electrodes of a target dummy driving transistor in a target dummy driving circuitry through the test pads; determining a characteristic of the target dummy driving transistor in accordance with the obtained signals; and adjusting a layout of a compensation structure in the display substrate in accordance with the characteristic of the target dummy driving transistor.

### BRIEF DESCRIPTION OF THE DRAWINGS

The accompanying drawings described herein are used to provide a further understanding of the present disclosure and constitute a part of the present disclosure, and the schematic embodiments of the present disclosure and the description thereof are used to explain the present disclosure and do not constitute an improper limitation on the present disclosure. In the accompanying drawings:

FIG. 1 shows a circuit structure of a normal driving circuitry according to an embodiment of the present disclosure;

FIG. 2 is a driving timing diagram of a normal driving circuitry according to an embodiment of the present disclosure;

FIG. 3 is a schematic view showing a position of a test pad according to an embodiment of the present disclosure;

FIG. 4 is a schematic view showing a first region and a second region according to an embodiment of the present disclosure;

FIG. 5 is a schematic view of a compensation structure according to an embodiment of the present disclosure;

FIG. 6 is a schematic view showing a position of a target dummy driving circuitry according to an embodiment of the present disclosure;

FIG. 7 is a schematic view of reusing a signal line as a signal lead-out line according to an embodiment of the present disclosure;

FIG. 8 is a schematic view of a normal driving circuitry and a target dummy driving circuitry according to an embodiment of the present disclosure;

FIG. 9a is a schematic layout view of an active layer in FIG. 8;

FIG. 9b is a schematic layout view of a first gate metal layer in FIG. 8;

FIG. 9c is a schematic layout view of a first source-drain metal layer in FIG. 8;

FIG. 10 is a sectional view along line B1-B2 in FIG. 8;

FIG. 11 is a sectional view along line C1-C2 in FIG. 8;

FIG. 12 is another schematic view of a compensation structure according to an embodiment of the present disclosure; and

FIG. 13 is an enlarged view of first compensation patterns and via holes included in second compensation patterns corresponding to the portion A in FIG. 12.

### DETAILED DESCRIPTION

In order to further describe the display substrate, the inspection method thereof and the display device. The present disclosure will be described hereinafter with reference to the drawings.

When a camera is arranged in an under-screen camera region of the display product, in order to ensure the image pickup effect, only light-emitting elements are arranged in the under-screen camera region, and driving circuitries for driving the light-emitting elements are arranged at the periphery of the under-screen camera region. Anode patterns of the light-emitting elements may be coupled to corresponding driving circuitries through connection lines to receive driving signals provided by the driving circuitries, so as to achieve light emission of the light-emitting elements.

Because the driving circuitries are arranged at the periphery of the under-screen camera region, the periphery has more film layers and a higher density of film layers, which is significantly different from the under-screen camera region. This difference will cause deviations of the characteristics of the driving transistors in the driving circuitries at the periphery of the under-screen camera region, particularly, the characteristics of the driving transistors in the driving circuitries close to the under-screen camera region will experience substantial deviations, which will cause abnormal display brightness at the periphery of the under-screen camera region, resulting in a visible bright ring at the periphery of the under-screen camera region and ultimately affecting the display effect of the display product.

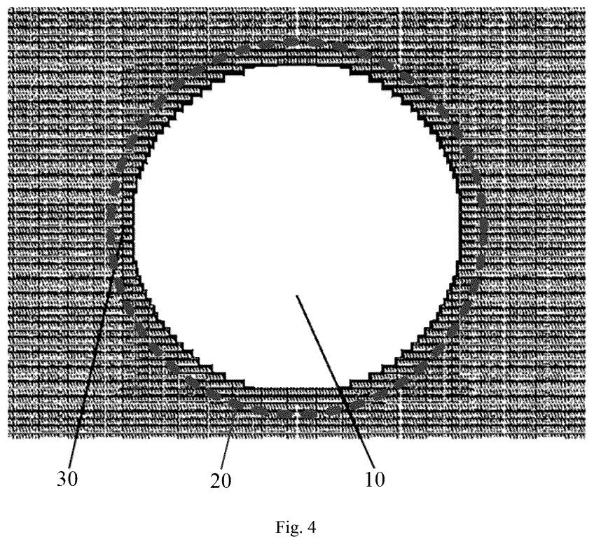

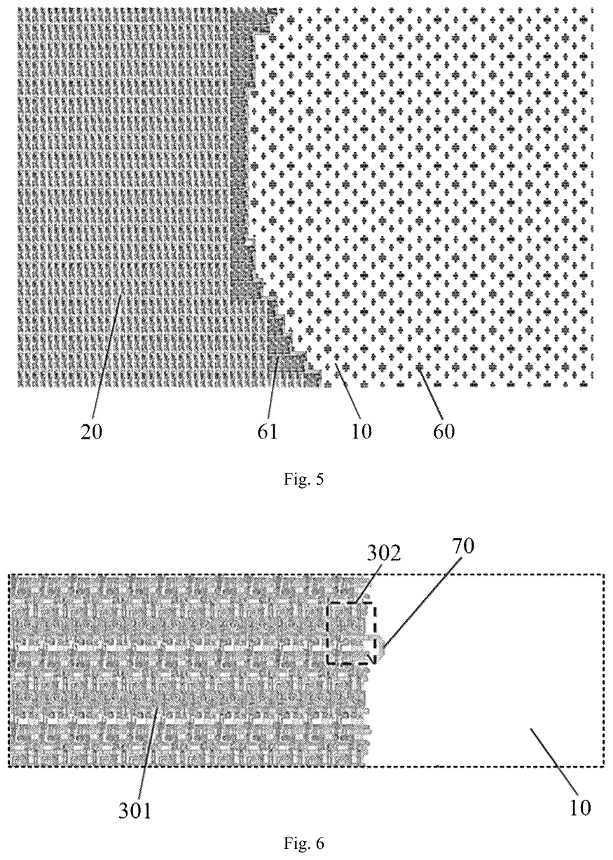

Referring to FIG. 3, FIG. 4, FIG. 5 and FIG. 6, the present disclosure provides in some embodiments a display substrate, which includes a base substrate including a first region 10 and a second region 20. The second region 20 includes a plurality of driving circuitries 30, the plurality of driving circuitries 30 include a plurality of normal driving circuitries 301 and a plurality of dummy driving circuitries; each of the normal driving circuitries 301 includes a normal driving transistor, each of the dummy driving circuitries includes a dummy driving transistor, and some of the normal driving circuitries 301 is used for driving an anode pattern in the first region 10; and the plurality of driving circuitries are divided into a plurality of driving circuitry columns, all of the driving circuitry columns surround the first region 10, and each of the driving circuitry columns surrounds a driving circuitry column located between the each of the driving circuitry columns and the first region 10.

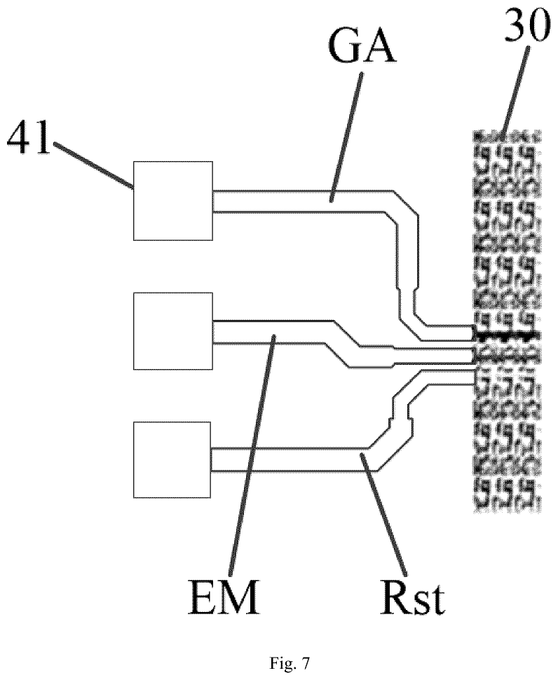

As shown in FIG. 3 and FIG. 7, the display substrate further includes a plurality of signal lead-out lines 40 and a plurality of test pads 41, and each of the signal lead-out lines 40 is coupled to a corresponding test pad 41.

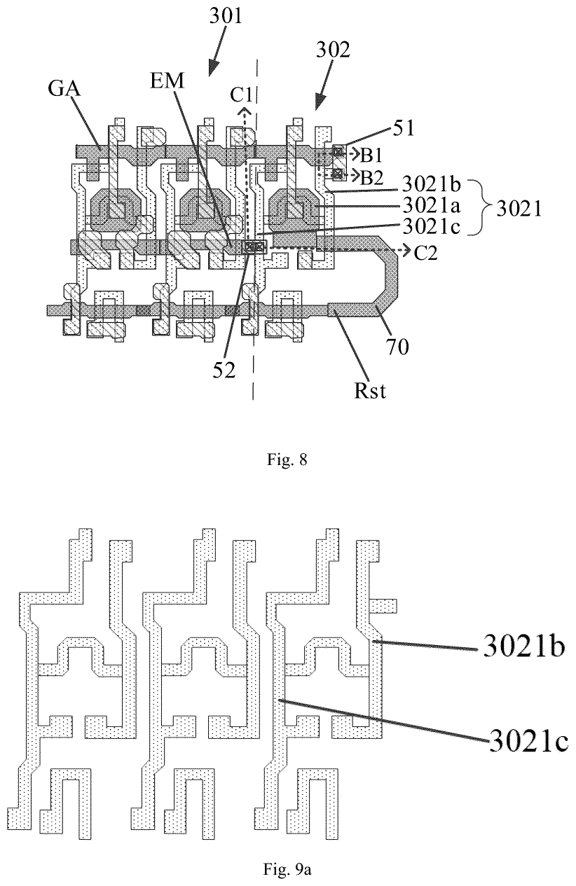

As shown in FIG. 8, in at least some of the driving circuitry columns, at least one electrode of a target dummy driving transistor 3021 in a target dummy driving circuitry 302 is coupled to at least one signal lead-out line 40.

For example, the display substrate may adopt a full display with camera (FDC) technology, in which the display product mainly includes a first region 10 and a normal display region, a camera is arranged in the first region 10, and a plurality of first sub-pixels and a plurality of second sub-pixels are distributed in the normal display region, each first sub-pixel includes a normal driving circuitry 301, each second sub-pixel includes a normal driving circuitry 301 and a dummy driving circuitry, the normal driving circuitry 301 in the first sub-pixels is used to drive the light-emitting element in the normal display region; the normal driving circuitry 301 in the second sub-pixels is used to drive the light-emitting element in the first region 10, and the dummy driving circuitry in the second sub-pixels is not used to drive the light-emitting element. In the normal display region, a plurality of first sub-pixels are divided into a plurality of first sub-pixel columns, the plurality of first sub-pixel columns are divided into a plurality of circuit groups, each circuit group includes at least one sub-pixel column; the plurality of second sub-pixels are divided into a plurality of second sub-pixel columns, and the circuit groups and the second sub-pixel columns are alternately arranged along a first direction.

For example, when the display substrate adopts the FDC technology, the second region 20 is located in the normal display region.

For example, the display substrate may adopt an AA hole technology, in which the display product mainly includes a first region 10, a first display region and a second display region. At least a part of the second display region is located between the first display region and the first region 10. The pixel density of the second display region is less than the pixel density of the first display region. When the display substrate adopts the AA hole technology, the second region 20 is located in the second display region.

For example, the base substrate includes a first region 10 and a second region 20, and the second region 20 surrounds the first region 10. A shape of the first region 10 includes a circular shape, a rectangular shape, an irregular shape, etc.

For example, the second region 20 includes a plurality of driving circuitries, and the plurality of driving circuitries include a plurality of normal driving circuitries 301 and a plurality of dummy driving circuitries. Each normal driving circuitry 301 includes, but not limited to, a 7T1C circuit structure. A circuit structure of the dummy driving circuitry may be the same as or different from a circuit structure of the normal driving circuitry 301. Some of the normal driving circuitries 301 are used to drive the anode pattern in the first region 10. The other normal driving circuitries of the normal driving circuitries 301 are used to drive the anode pattern in the second region 20.

For example, the dummy driving circuitries include some of the transistors in the normal driving circuitries 301, but the present disclosure is not limited thereto.

For example, the plurality of driving circuitries are divided into a plurality of driving circuitry columns, the plurality of driving circuitry columns are sequentially arranged in a nested manner, i.e., each of the driving circuitry columns surrounds the first region 10, and each driving circuitry column surrounds other driving circuitry column located between the each driving circuitry column and the first region 10. Each driving circuitry column includes at least one of the normal driving circuitry 301 or the dummy driving circuitry.

For example, each driving circuitry column includes the plurality of normal driving circuitries 301 and the plurality of dummy driving circuitries at the same time.

For example, the plurality of signal lead-out lines 40 are coupled to the plurality of test pads 41 in a one-to-one manner. The signal lead-out lines 40 and the test pad 41 to which the signal lead-out lines 40 is coupled are formed into an integral structure.

For example, the signal lead-out line may be made of a single electrically conductive material layer, or may be made of an electrically conductive material layer already used in the display substrate. The signal lead-out line 40 may be an independent signal lead-out line 40 only for transmitting a test signal, or an existing signal line in the display substrate may be reused as the signal lead-out line 40.

For example, minimum distances between the normal driving circuitries 301 and/or the dummy driving circuitries in a same driving circuitry column and the under-screen camera region are equal. The characteristics of the transistors in the normal driving circuitries 301 and/or the dummy driving circuitries in a same driving circuitry column have substantially the same deviation.

For example, at least some of the driving circuitry columns include at least one dummy driving circuitry, and the at least one dummy driving circuitry includes at least one target dummy driving circuitry 302, the target dummy driving circuitry 302 includes a target dummy driving transistor 3021, and electrodes of the target dummy driving transistor 3021 are coupled to corresponding signal lead-out lines 40, respectively. It should be appreciated that, the target dummy driving circuitry 302 refers to a dummy driving circuitry selected from the driving circuitry columns for testing, and a specific structure of the target dummy driving circuitry 302 may be the same as that of other dummy driving circuitries.

According to the specific structure of the above-mentioned display substrate, in the display substrate according to the embodiment of the present disclosure, the electrodes of the target dummy driving transistor 3021 in the target dummy driving circuitry 302 selected from at least some of the driving circuitry columns are coupled to corresponding signal lead-out lines 40 respectively, and the signal lead-out lines 40 are coupled to corresponding test pads 41. In this way, the signals of the electrodes of the target dummy driving transistor 3021 may be monitored in real time through the signal lead-out lines 40 and the test pads 41, so as to obtain the characteristics and a threshold voltage drift of the target dummy driving transistor 3021. Based on the characteristics and the threshold voltage drift of the target dummy driving transistor 3021, defect analysis is performed to determine the degree of impact of the first region 10 on the target dummy driving transistor 3021. According to the determined result, a corresponding compensation scheme is implemented on the display substrate, so as to solve the problem that the characteristics of the driving transistors in the driving circuitries surrounding the first region 10 experience deviations due to the difference between the first region 10 and the second region 20, which ultimately affects the display effect of the display product.

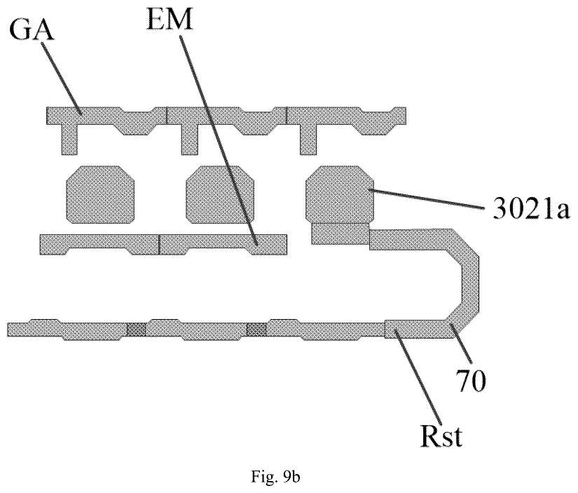

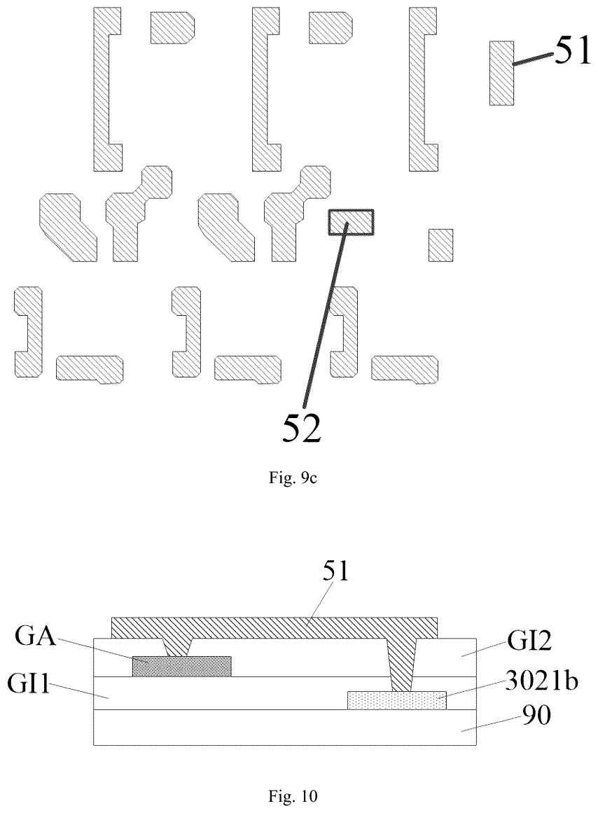

As shown in FIG. 3, FIG. 7, FIG. 8, and FIG. 9a to FIG. 9c, in some embodiments of the present disclosure, the plurality of driving circuitries are divided into a plurality of driving circuitry rows, each of the driving circuitry rows includes at least one of the driving circuitries that is arranged in a first direction; and the display substrate further includes a plurality of signal lines, at least a part of each signal line extends along the first direction, and the signal lines are coupled to driving circuitries in corresponding driving circuitry rows respectively; and a signal line correspondingly coupled to a driving circuitry row to which a target dummy driving transistor 3021 belongs is reused as the signal lead-out line 40 coupled to the target dummy driving transistor 3021.

It should be appreciated that, the second gate metal layer is not shown in FIG. 8. The normal driving circuitry 301 includes the second gate metal layer, and the second gate metal layer may be used to form structures such as a second electrode plate of a capacitor and an initialization signal line, but the present disclosure is not limit thereto. The second gate metal layer may or may not be provided in the target dummy driving circuitry 302 according to actual needs.

For example, the display substrate further includes other display regions surrounding the second region 20, and the other display regions include a plurality of sub-pixels arranged in an array, and each of the sub-pixels includes a normal driving circuitry 301 and a light-emitting element.

For example, the plurality of driving circuitries in the second region 20 are divided into a plurality of driving circuitry rows, each of the driving circuitry rows may be arranged in the same row as a driving circuitry row in the other display regions, and the driving circuitries located in the same row share a same gate line GA, reset line Rst, light-emitting control line EM and the like.

For example, each driving circuitry in each of the driving circuitry rows includes a normal driving circuitry 301 and a dummy driving circuitry.

For example, a signal line correspondingly coupled to a driving circuitry row to which the target dummy driving transistor 3021 belongs is reused as the signal lead-out line 40 coupled to the target dummy driving transistor 3021. During a normal display period, the signal line is used to provide the display substrate with corresponding scanning signals. During an inspection (ins) period, the signal line is reused as the signal lead-out line 40 to provide inspection signals and obtain signals on electrodes of the target dummy driving transistor 3021.

It should be appreciated that, the signal line extending along the first direction means that the signal line includes a main portion and a secondary portion coupled to the main portion, the main portion is a line-shaped, a line segment-shaped, or a strip-shaped body, the main portion extends along the first direction, and a length of the main portion extending along the first direction is greater than a length of the secondary portion extending along other directions.

In the display substrate according to the embodiments of the present disclosure, the signal line correspondingly coupled to the driving circuitry row to which the target dummy driving transistor 3021 belongs is reused as the signal lead-out line 40 coupled to the target dummy driving transistor 3021, thus it is able to achieve not only a normal display function of the display substrate, but also an inspection function, thereby effectively reducing the layout difficulty of the display substrate, and simplify the internal structure of the display substrate.

As shown in FIG. 3, FIG. 7 and FIG. 8, in some embodiments of the present disclosure, the plurality of signal lines include a plurality of gate lines GA, a plurality of light-emitting control lines EM and a plurality of reset lines Rst; each of the driving circuitry rows is coupled to a corresponding gate line GA, a corresponding light-emitting control line EM and a corresponding reset line Rst; and at least one of the gate line GA, the light-emitting control line EM or the reset line Rst correspondingly coupled to the driving circuitry row to which the target dummy driving transistor 3021 belongs is reused as the signal lead-out line 40 coupled to the target dummy driving transistor 3021.

For example, the signal lines extend to one end of the bezel region of the display substrate, and are coupled to the corresponding test pads 41 and the corresponding gate electrode 3021a driving circuitries (gate driver on array, GOA) respectively.

In the display substrate according to the embodiments of the present disclosure, at least one of the gate line GA, the light-emitting control line EM or the reset line Rst correspondingly coupled to the driving circuitry row to which the target dummy driving transistor 3021 belongs is reused as the signal lead-out line 40 coupled to the target dummy driving transistor 3021, thus it is able to achieve not only the normal display function of the display substrate, but also the inspection function, thereby effectively reducing the layout difficulty of the display substrate, and simplifying the internal structure of the display substrate.

As shown in FIG. 3, FIG. 7 and FIG. 8, in some embodiments of the present disclosure, the reset line Rst correspondingly coupled to the driving circuitry row to which the target dummy driving transistor 3021 belongs is reused as the signal lead-out line 40 coupled to a gate electrode 3021a of the target dummy driving transistor 3021; the gate line GA correspondingly coupled to the driving circuitry row to which the target dummy driving transistor 3021 belongs is reused as the signal lead-out line 40 coupled to a first electrode 3021b of the target dummy driving transistor 3021; and the light-emitting control line EM correspondingly coupled to the driving circuitry row to which the target dummy driving transistor 3021 belongs is reused as the signal lead-out line 40 coupled to a second electrode 3021c of the target dummy driving transistor 3021.

For example, the first electrode 3021b of the target dummy driving transistor 3021 includes a drain electrode, and the second electrode 3021c of the target dummy driving transistor 3021 includes a source electrode.

According to the above arrangement, it is able to achieve not only the normal display function of the display substrate, but also the inspection function, thereby effectively reducing the layout difficulty of the display substrate, and simplifying the internal structure of the display substrate.

As shown in FIG. 3, FIG. 6, FIG. 7 and FIG. 8, in some embodiments of the present disclosure, the reset line Rst correspondingly coupled to the driving circuitry row to which the target dummy driving transistor 3021 belongs and the gate electrode 3021a of the target dummy driving transistor 3021 are formed into an integral structure.

For example, both the reset line Rst and the gate electrode 3021a of the target dummy driving transistor 3021 are made of a first gate metal layer.

For example, one end of the reset line Rst that is coupled to the gate electrode 3021a of the target dummy driving transistor 3021 extends to form a bend portion 70, and the bend portion 70 and the gate electrode 3021a of the target dummy driving transistor 3021 are formed into an integral structure. For example, the bend portion 70 is of an arc shape, or a semicircular shape. An opening of the bend portion 70 is oriented toward the target dummy driving circuitry 302.

The reset line Rst correspondingly coupled to the driving circuitry row to which the target dummy driving transistor 3021 belongs and the gate electrode 3021a of the target dummy driving transistor 3021 are formed into an integral structure, thus it is able to form the gate electrode 3021a of the target dummy driving transistor 3021 and the reset line Rst through one patterning process, thereby not only simplifying the manufacturing process of the display substrate, but also effectively improving the reliability of the electrical connection between the gate electrode 3021a and the reset line Rst.

As shown in FIG. 8, FIG. 10 and FIG. 11, in some embodiments of the present disclosure, the target dummy driving circuitry 302 includes a first electrically conductive connection portion 51; and the gate line GA correspondingly coupled to the driving circuitry row to which the target dummy driving transistor 3021 belongs is coupled to the first electrode 3021b of the target dummy driving transistor 3021 through the first electrically conductive connection portion 51.

It should be appreciated that, FIG. 10 and FIG. 11 further show the base substrate 90, the first gate insulation layer GI1 and the second gate insulation layer GI2.

For example, the first electrically conductive connection portion 51 is made of the first source-drain metal layer, and may be formed in a same patterning process as other electrically conductive structures made of the first source-drain metal layer in the display substrate.

For example, there is an overlapping region between an orthogonal projection of the first electrically conductive connection portion 51 onto the base substrate and an orthogonal projection of the gate line GA onto the base substrate. In the overlapping region, the first electrically conductive connection portion 51 is coupled to the gate line GA through a via hole. There is an overlapping region between the orthogonal projection of the first electrically conductive connection portion 51 onto the base substrate and an orthogonal projection of the first electrode 3021b of the target dummy driving transistor 3021 onto the base substrate. In the overlapping region, the first electrically conductive connection portion 51 is coupled to the first electrode 3021b of the target dummy driving transistor 3021 through a via hole.

The arrangement of the first electrically conductive connection portion 51 can effectively reduce the difficulty in establishing a connection between the gate line GA correspondingly coupled to the driving circuitry row to which the target dummy driving transistor 3021 belongs and the first electrode 3021b of the target dummy driving transistor 3021, thereby ensuring the reliability of the connection.

As shown in FIG. 8, in some embodiments of the present disclosure, the target dummy driving circuitry 302 includes a second electrically conductive connection portion 52; and the light-emitting control line EM correspondingly coupled to the driving circuitry row to which the target dummy driving transistor 3021 belongs is coupled to the second electrode 3021c of the target dummy driving transistor 3021 through the second electrically conductive connection portion 52.

For example, the second electrically conductive connection portion 52 is made of the first source-drain metal layer, and may be formed in a same patterning process as other electrically conductive structures made of the first source-drain metal layer in the display substrate.

For example, there is an overlapping region between an orthogonal projection of the second electrically conductive connection portion 52 onto the base substrate and an orthogonal projection of the light-emitting control line EM onto the base substrate. In the overlapping region, the second electrically conductive connection portion 52 is coupled to the light-emitting control line EM through a via hole. There is an overlapping region between the orthogonal projection of the second electrically conductive connection portion 52 onto the base substrate and an orthogonal projection of the second electrode 3021c of the target dummy driving transistor 3021 onto the base substrate. In the overlapping region, the second electrically conductive connection portion 52 is coupled to the second electrode 3021c of the target dummy driving transistor 3021 through a via hole.

The arrangement of the second electrically conductive connection portion 52 can effectively reduce the difficulty in establishing a connection between the light-emitting control line EM correspondingly coupled to the driving circuitry row to which the target dummy driving transistor 3021 belongs and the second electrode 3021c of the target dummy driving transistor 3021, thereby ensuring the reliability of the connection.

In some embodiments of the present disclosure, the display substrate includes the first source-drain metal layer, and the first electrically conductive connection portion 51 and/or the second electrically conductive connection portion 52 are made of the first source-drain metal layer.

In some embodiments of the present disclosure, the at least some of the driving circuitry columns include an odd quantity of driving circuitry columns or an even quantity of driving circuitry columns.

For example, in the at least some of the driving circuitry columns, electrodes of the target dummy driving transistor 3021 in the target dummy driving circuitry 302 are coupled to the corresponding signal lead-out lines 40, respectively.

For example, in the odd quantity of driving circuitry columns, electrodes of the target dummy driving transistor 3021 in the target dummy driving circuitry 302 are coupled to the corresponding signal lead-out lines 40, respectively.

For example, in the even quantity of driving circuitry columns, electrodes of the target dummy driving transistor 3021 in the target dummy driving circuitry 302 are coupled to the corresponding signal lead-out lines 40, respectively.

In some embodiments of the present disclosure, adjacent driving circuitry columns in the at least some of the driving circuitry columns are spaced apart by at least one other driving circuitry column, and the other driving circuitry column does not include the target dummy driving circuitry.

For example, in the at least some of the driving circuitry columns, there are five other driving circuitry columns between adjacent driving circuitry columns.

In the display substrate according to the embodiments of the present disclosure, the at least some of the driving circuitry columns may be spaced apart from each other, and there is no need to collect electrode signals of the dummy driving transistors in each driving circuitry column, thereby meeting collection requirements and reducing the complexity of the display substrate.

In some embodiments of the present disclosure, the display substrate further includes an active layer, a first gate insulation layer, a first gate metal layer, a second gate insulation layer, a second gate metal layer, an interlayer insulation layer and a first source-drain metal layer stacked sequentially in a direction away from the base substrate; and the first region 10 further includes a compensation structure, the compensation structure is made of at least one of the active layer, the first gate insulation layer, the first gate metal layer, the second gate insulation layer, the second gate metal layer, the interlayer insulation layer or the first source-drain metal layer.

For example, when the compensation structure is made of at least one of the active layer, the first gate insulation layer, the first gate metal layer, the second gate insulation layer, the second gate metal layer, the interlayer insulation layer or the first source-drain metal layer, the specific structure of the compensation structure may be the same as the structure formed in the second region 20 by the film layers adopted by the compensation structure, but the present disclosure is not limited thereto.

In the display substrate according to the embodiments of the present disclosure, the signals of the electrodes of the target dummy driving transistor 3021 are monitored in real time through the signal lead-out lines 40 and the test pads 41, so as to obtain the characteristics and a threshold voltage drift of the target dummy driving transistor 3021. Based on the characteristics and the threshold voltage drift of the target dummy driving transistor 3021, defect analysis is performed to determine the degree of impact of the first region 10 on the target dummy driving transistor 3021. According to the determined result, a corresponding compensation scheme is implemented on the display substrate, so as to solve the problem that the characteristics of the driving transistors in the driving circuitries surrounding the first region 10 experience deviations due to the difference between the first region 10 and the second region 20, which ultimately affects the display effect of the display product.

Based on the above idea, subsequent to obtaining the determined result, it is able to arrange the compensation structure in the first region 10 to reduce the structure difference between the first region 10 and the second region 20, so as to reduce the degree of impact of the first region 10 on the normal driving transistors and the dummy driving transistors, and ensure operation performance of the normal driving transistors.

As shown in FIG. 5, in some embodiments of the present disclosure, the compensation structure includes compensation patterns 60 uniformly distributed throughout the first region 10.

According to the above arrangement, it is able to compensate the entire first region 10, which effectively reduces the structure difference between the first region 10 and the second region 20, so as to reduce the degree of impact of the first region 10 on the normal driving transistors and the dummy driving transistors, and ensure operation performance of the normal driving transistors.

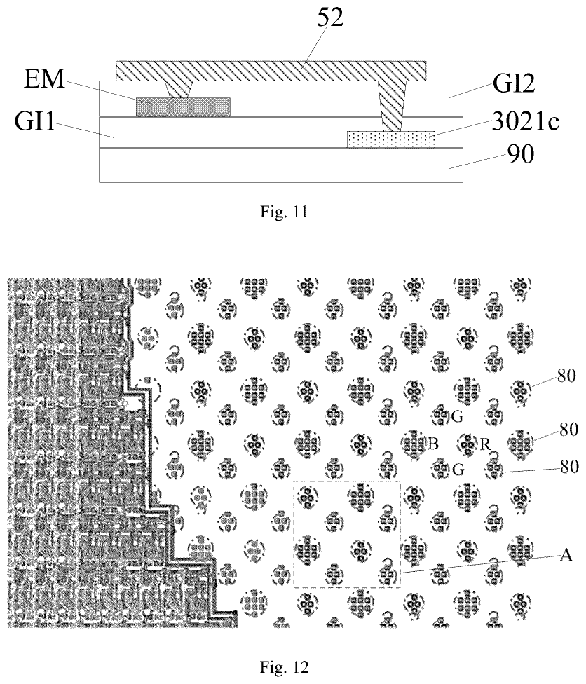

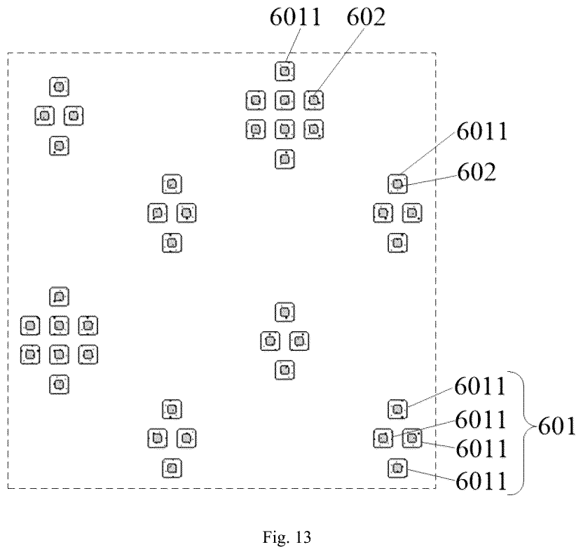

As shown in FIG. 12 and FIG. 13, in some embodiments of the present disclosure, the first region 10 includes a plurality of anode patterns 80, the compensation structure includes a plurality of first compensation patterns 601 and a plurality of second compensation patterns; an orthogonal projection of the first compensation pattern 601 onto the base substrate at least partially overlaps an orthogonal projection of a corresponding anode pattern 80 onto the base substrate, an orthogonal projection of the second compensation pattern onto the base substrate at least partially overlaps an orthogonal projection of a corresponding anode pattern 80 onto the base substrate; and the first compensation patterns 601 are arranged at a layer different from the second compensation patterns.

For example, the dotted box in FIG. 12 depicts an outline of a corresponding anode pattern 80.

For example, the orthogonal projection of the first compensation pattern 601 onto the base substrate is covered by the orthogonal projection of the corresponding anode pattern 80 onto the base substrate.

For example, the orthogonal projection of the second compensation pattern onto the base substrate is covered by the orthogonal projection of the corresponding anode pattern 80 onto the base substrate.

For example, the anode patterns 80 include light transmitting anode patterns or opaque anode patterns.

According to the above arrangement, the first compensation patterns 601 and the second compensation patterns may be shielded by the anode patterns 80, so as to prevent the first compensation patterns 601 and the second compensation patterns from affecting the light transmittance of the first region 10, thereby to ensure the transmittance of the first region 10.

According to the above arrangement, it is able to compensate the entire first region 10, which effectively reduces the structure difference between the first region 10 and the second region 20, so as to reduce the degree of impact of the first region 10 on the normal driving transistors and the dummy driving transistors, and ensure operation performance of the normal driving transistors.

As shown in FIG. 12 and FIG. 13, in some embodiments of the present disclosure, the first compensation patterns 601 each include a plurality of independent sub-compensation patterns 6011, and an orthogonal projection of the sub-compensation pattern 6011 onto the base substrate at least partially overlaps an orthogonal projection of a corresponding anode pattern 80 onto the base substrate.

According to the above arrangement, it is able to reduce the influence of the first region 10 on the normal driving transistors and the dummy driving transistors, and meanwhile reduce the degree of impact of the first compensation patterns 601 on the light transmittance of the first region 10 to the maximum extent.

As shown in FIG. 12 and FIG. 13, in some embodiments of the present disclosure, the second compensation patterns each include a plurality of via holes 602, and an orthogonal projection of the via hole 602 onto the base substrate at least partially overlaps an orthogonal projection of a corresponding anode pattern 80 onto the base substrate.

For example, the second compensation patterns each include a body structure and a plurality of via holes provided in the body structure.

For example, an outline of the body structure is substantially the same as the outline of the anode pattern covering the body structure.

For example, a boundary of the body structure roughly fits with a boundary of the first region 10.

For example, the plurality of via holes of the second compensation pattern may be completely covered by the anode pattern 80.

For example, a quantity of the via holes of the second compensation pattern may be set according to actual needs.

In some embodiments of the present disclosure, an orthogonal projection of the via holes of the second compensation pattern corresponding to the anode pattern onto the base substrate is covered by an orthogonal projection of the sub-compensation patterns corresponding to the anode pattern onto the base substrate.

According to the above arrangement, it is able to reduce the influence of the first region 10 on the normal driving transistors and the dummy driving transistors, and meanwhile reduce the degree of impact of the first compensation patterns 601 and the second compensation patterns on the light transmittance of the first region 10 to the maximum extent.

In some embodiments of the present disclosure, the first compensation patterns are made of the active layer, and the second compensation patterns are made of the interlayer insulation layer.

In some embodiments of the present disclosure, the plurality of anode patterns 80 include a plurality of first anode patterns, a plurality of second anode patterns and a plurality of third anode patterns, and colors of sub-pixels corresponding to the first anode pattern, the second anode pattern and the third anode pattern are different; and at least two of the first anode pattern, the second anode pattern and the third anode pattern correspond to the first compensation patterns with different areas, and correspond to the second compensation patterns with different areas.

For example, the larger the area of the anode pattern is, the larger the area of the first compensation pattern corresponding to the anode pattern is. The smaller the area of the anode pattern is, the smaller the area of the first compensation pattern corresponding to the anode pattern is.

For example, the larger the area of the anode pattern is, the larger the area of the second compensation pattern corresponding to the anode pattern is. The smaller the area of the anode pattern is, the smaller the area of the second compensation pattern corresponding to the anode pattern is.

In some embodiments of the present disclosure, two of the first anode pattern, the second anode pattern and the third anode pattern correspond to the first compensation patterns with a same area, and correspond to the second compensation patterns with a same area.

In some embodiments of the present disclosure, the first anode pattern corresponds to a blue sub-pixel, the second anode pattern corresponds to a red sub-pixel, and the third anode pattern corresponds to a green sub-pixel; an area of the first compensation pattern corresponding to the first anode pattern is greater than an area of the first compensation pattern corresponding to the second anode pattern; and a quantity of the via holes corresponding to the first anode pattern is greater than a quantity of the via holes corresponding to the second anode pattern.

For example, an area of the first anode pattern is greater than an area of the second anode pattern, and an area of the second anode pattern is substantially the same as an area of the third anode pattern.

In some embodiments of the present disclosure, the compensation patterns 60 are made of one of the active layer, the first gate insulation layer, the first gate metal layer, the second gate insulation layer, the second gate metal layer, the interlayer insulation layer and the first source-drain metal layer.

For example, the compensation patterns 60 are made of the active layer.

As shown in FIG. 5, in some embodiments of the present disclosure, the compensation structure includes a plurality of compensation driving circuitries 61, and a circuit structure of each of the compensation driving circuitries 61 is the same as a circuit structure of the dummy driving circuitry or a circuit structure of the normal driving circuitry 301.

In the display substrate according to the embodiments of the present disclosure, the signals of the electrodes of the target dummy driving transistor 3021 are monitored in real time through the signal lead-out lines 40 and the test pads 41, so as to obtain the characteristics and a threshold voltage drift of the target dummy driving transistor 3021. Based on the characteristics and the threshold voltage drift of the target dummy driving transistor 3021, defect analysis is performed to determine the degree of impact of the first region 10 on the target dummy driving transistor 3021. According to the determined result, a corresponding compensation scheme is implemented on the display substrate, so as to solve the problem that the characteristics of the driving transistors in the driving circuitries surrounding the first region 10 experience deviations due to the difference between the first region 10 and the second region 20, which ultimately affects the display effect of the display product.

Based on the above idea, subsequent to obtaining a determined result, it is able to arrange a plurality of compensation driving circuitries 61 in the first region 10 to reduce the structure difference between the first region 10 and the second region 20, so as to reduce the degree of impact of the first region 10 on the normal driving transistors and the dummy driving transistors, and ensure operation performance of the normal driving transistors.

As shown in FIG. 5, in some embodiments of the present disclosure, the plurality of compensation driving circuitries 61 are divided into at least two columns of compensation driving circuitries 61, the at least two columns of compensation driving circuitries 61 are sequentially arranged in a nested manner, and the at least two columns of compensation driving circuitries 61 are located at an edge of the first region 10.

For example, the at least two columns of compensation driving circuitries 61 include two columns of compensation driving circuitries 61 or four columns of compensation driving circuitries 61.

The at least two columns of compensation driving circuitries 61 are located at the edge of the first region 10, so that the at least two columns of compensation driving circuitries 61 are close to the second region 20, which can effectively reduce the structure difference between the edge of the first region 10 and the second region 20, so as to reduce the degree of impact of the first region 10 on the normal driving transistors and the dummy driving transistors, and ensure operation performance of the normal driving transistors.

In the display substrate according to the embodiments of the present disclosure, whether present compensation structure design schemes are effective may be verified according to the monitoring results, and a most effective compensation structure design scheme may be determined. At the same time, target dummy driving circuitries 302 under different impacts may be differentiated according to the monitoring results, and a gradient compensation design may be achieved. The above inspection scheme may provide data support for how to make improvements after problems occur.

In some embodiments of the present disclosure, the plurality of test pads 41 are arranged in a bezel region of the display substrate.

For example, the plurality of test pads 41 are arranged in a left bezel region or a right bezel region of the display substrate.

For example, through bringing probes into contact with the test pads 41, it is able to input signals to the test pads 41 or obtain signals on the test pads 41.

In some embodiments of the present disclosure, the first region 10 includes the under-screen camera region, and the second region 20 includes a transition region.

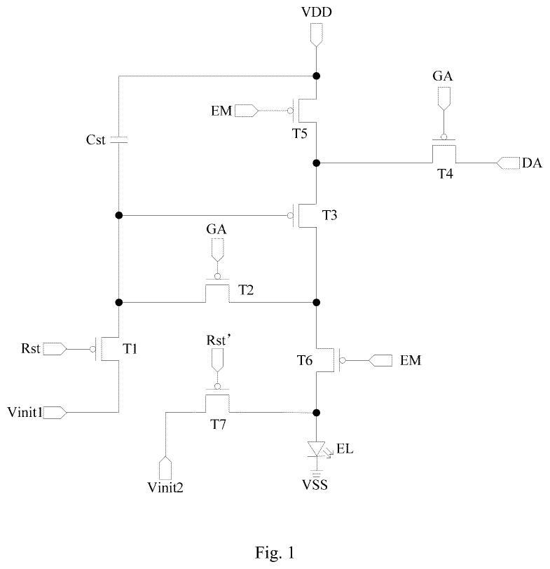

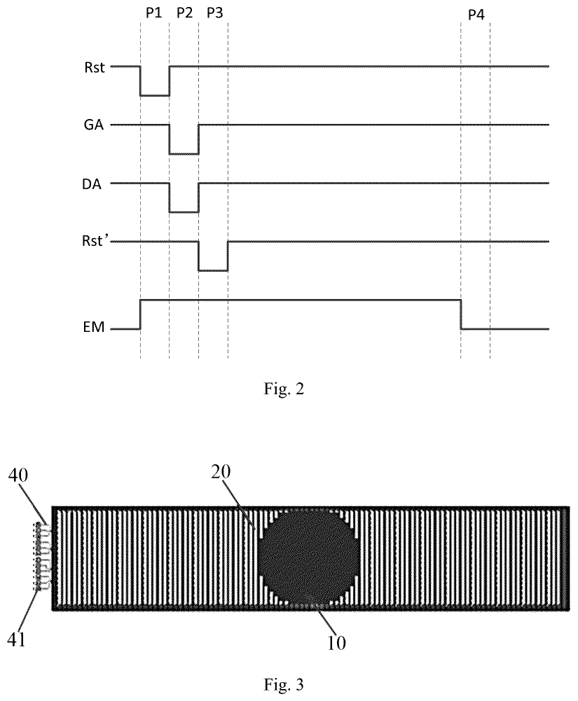

As shown in FIG. 1 and FIG. 2, in some embodiments of the present disclosure, the display substrate further includes a plurality of reset lines Rst, a plurality of data lines DA, a plurality of gate lines GA, a plurality of light-emitting control lines EM, a plurality of power supply lines VDD, a plurality of first initialization signal lines Vinit1 and a plurality of second initialization signal lines Vinit2.

The normal driving circuitry 301 includes a first reset transistor T1, a compensation transistor T2, a driving transistor T3, a data writing transistor T4, a power control transistor T5, a light-emitting control transistor T6, a second reset transistor T7, and a storage capacitor Cst.

A gate electrode of the first reset transistor T1 is coupled to a corresponding reset line Rst, a first electrode of the first reset transistor T1 is coupled to a corresponding first initialization signal line Vinit1, and a second electrode of the first reset transistor T1 is coupled to a gate electrode of the driving transistor T3.

A gate electrode of the compensation transistor T2 is coupled to a corresponding gate line GA, a first electrode of the compensation transistor T2 is coupled to a second electrode of the driving transistor T3, and a second electrode of the compensation transistor T2 is coupled to the gate electrode of the driving transistor T3.

A gate electrode of the data writing transistor T4 is coupled to a corresponding gate line GA, a first electrode of the data writing transistor T4 is coupled to a corresponding data line DA, and a second electrode of the data writing transistor T4 is coupled to a first electrode of the driving transistor T3.

A gate electrode of the power control transistor T5 is coupled to a corresponding light-emitting control signal line, a first electrode of the power control transistor T5 is coupled to the power supply line VDD, and a second electrode of the power control transistor T5 is coupled to the first electrode of the driving transistor T3.

A gate electrode of the light-emitting control transistor T6 is coupled to the corresponding light-emitting control signal line, a first electrode of the light-emitting control transistor T6 is coupled to the second electrode of the driving transistor T3, and a second electrode of the light-emitting control transistor T6 is coupled to a light-emitting element EL of a sub-pixel; and an cathode of the light-emitting element EL receives a negative power supply signal VSS.

A gate electrode of the second reset transistor T7 and a gate electrode of a first reset transistor T1 in an adjacent driving circuitry in the second direction are coupled to a same reset line Rst′. A first electrode of the second reset transistor T7 is coupled to a corresponding second initialization signal line Vinit2, and a second electrode of the second reset transistor T7 is coupled to an anode of the light-emitting element EL. The second reset transistor T7 is used to reset the anode of the light-emitting element EL.

As shown in FIG. 1 and FIG. 2, when the normal driving circuitry 301 with the aforementioned structure is in operation, each operation cycle includes a first reset period P1, a write compensation period P2, a second reset period P3, and a light-emitting period P4.

During the first reset period P1, a reset signal inputted by the reset line Rst is at an active level, the first reset transistor T1 is turned on, and a first initialization signal transmitted by the first initialization signal line Vinit1 is inputted to the gate electrode T3-g of the driving transistor T3, such that a gate-source voltage Vgs held in the driving transistor T3 during a previous frame is cleared, to reset the gate electrode T3-g of the driving transistor T3.

During the write compensation period P2, the reset signal is at a non-active level, the first reset transistor T1 is turned off, and a gate scanning signal inputted by the gate line GA is at an active level, to control the compensation transistor T2 and the data writing transistor T4 to be turned on. A data signal is written by the data line DA and transmitted to the first electrode of the driving transistor T3 through the data writing transistor T4, and meanwhile, the compensation transistor T2 and the data writing transistor T4 are turned on, so that the driving transistor T3 is formed into a diode structure. Therefore, the threshold voltage of the driving transistor T3 is compensated through the cooperation of the compensation transistor T2, the driving transistors T3 and the data writing transistor T4; when the compensation time is long enough, an electric potential at the gate electrode T3-g of the driving transistor T3 may be controlled to eventually reach Vdata+Vth, where Vdata represents a voltage value of the data signal, and Vth represents a threshold voltage of the driving transistor T3.

During the second reset period P3, the gate scanning signal is at a non-active level, the compensation transistor T2 and the data-writing transistor T4 are both turned off, and the reset signal inputted by the reset line Rst′ coupled to the next adjacent row of sub-pixels is at an active level, to control the second reset transistor T7 to be turned on, so that the initialization signal inputted by the second initialization signal line Vinit2 is inputted to the anode of the light-emitting element EL to control the light-emitting element EL not to emit light. The cathode of the light-emitting element EL is coupled to the negative power supply signal VSS.

During the light-emitting period P4, a light-emitting control signal written by the light-emitting control line EM is at an active level, to control the power control transistor T5 and the light-emitting control transistor T6 to be turned on, such that the power supply signal transmitted by the power supply line VDD is inputted to the first electrode of the driving transistor T3, meanwhile since the gate electrode T3-g of the driving transistor T3 is maintained at Vdata+Vth, the driving transistor T3 is turned on, and a gate-source voltage corresponding to the driving transistor T3 is Vdata+Vth-VDD, where VDD is a voltage value corresponding to the power supply signal. A leakage current resulting from the gate-source voltage flows to an anode of the corresponding light-emitting element EL, to drive the corresponding light-emitting element EL to emit light.

The present disclosure further provides in an embodiment a display device, which includes the above-mentioned display substrate.

It should be appreciate that, the display device may be any product or member having a display function, such as a television, a display, a digital photo frame, a mobile phone, a wrist watch and a tablet computer. The display device further includes a flexible circuit board, a printed circuit board, a back plate and the like.

In the display substrate according to the embodiments of the present disclosure, electrodes of the target dummy driving transistor 3021 in the target dummy driving circuitry 302 selected from at least some of the driving circuitry columns are coupled to corresponding signal lead-out lines 40, and the signal lead-out lines 40 are coupled to corresponding test pads 41. In this way, the signals of the electrodes of the target dummy driving transistor 3021 are monitored in real time through the signal lead-out lines 40 and the test pads 41, so as to obtain the characteristics and a threshold voltage drift of the target dummy driving transistor 3021. Based on the characteristics and the threshold voltage drift of the target dummy driving transistor 3021, defect analysis is performed to determine the degree of impact of the first region 10 on the target dummy driving transistor 3021. According to the determined result, a corresponding compensation scheme is implemented on the display substrate, so as to solve the problem that the characteristics of the driving transistors in the driving circuitries surrounding the first region 10 experience deviations due to the difference between the first region 10 and the second region 20, which ultimately affects the display effect of the display product.

In the display substrate according to the embodiments of the present disclosure, the signal line correspondingly coupled to a driving circuitry row to which the target dummy driving transistor 3021 belongs is reused as the signal lead-out line 40 coupled to the target dummy driving transistor 3021, which not only ensures a normal display function of the display substrate, but also provides an inspection function, thereby effectively reducing the layout difficulty of the display substrate, and simplifying the internal structure of the display substrate. In the display substrate according to the embodiments of the present disclosure, the reset line correspondingly coupled to the driving circuitry row to which the target dummy driving transistor 3021 belongs and the gate electrode of the target dummy driving transistor 3021 are formed into an integral structure, such that it is able to form the gate electrode of the target dummy driving transistor 3021 and the reset line through one patterning process, thereby not only simplifying the manufacturing process of the display substrate, but also effectively improving the reliability of the electrical connection between the gate electrode and the reset line. In the display substrate according to the embodiments of the present disclosure, the first electrically conductive connection portion 51 is provided, which effectively reduces the difficulty in establishing a connection between the gate line correspondingly coupled to the driving circuitry row to which the target dummy driving transistor 3021 belongs and the first electrode of the target dummy driving transistor 3021, so as to ensure the reliability of the connection. In the display substrate according to the embodiments of the present disclosure, the second electrically conductive connection portion 52 is provided, which effectively reduces the difficulty in establishing a connection between the light-emitting control line correspondingly coupled to the driving circuitry row to which the target dummy driving transistor 3021 belongs and the second electrode of the target dummy driving transistor 3021, so as to ensure the reliability of the connection.

When the display device according to the embodiment of the present disclosure includes the aforementioned display substrate, it is also able to achieve the same beneficial effects, which will not be repeated herein.

The present disclosure further provides in an embodiment an inspection method of a display substrate, for inspecting the above-mentioned display substrate. The method includes: inputting corresponding test signals to test pads 41 in the display substrate; obtaining signals of electrodes of a target dummy driving transistor 3021 in a target dummy driving circuitry 302 through the test pads 41; determining a characteristic of the target dummy driving transistor 3021 in accordance with the obtained signals; and adjusting a layout of a compensation structure in the display substrate in accordance with the characteristic of the target dummy driving transistor 3021.

For example, a 0V voltage signal is inputted to the drain electrode of the target dummy driving transistor 3021. Gradually changed voltage signals are inputted to the source electrode and the gate electrode of the target dummy driving transistor 3021.

For example, signals of the electrodes of the target dummy driving transistor 3021 in the target dummy driving circuitry 302 are obtained through the test pads 41, and a characteristic curve of the target dummy driving transistor 3021 is obtained.

For example, the layout of the compensation structure in the display substrate is adjusted according to the characteristic curve of the target dummy driving transistor 3021.

When the display substrate according to the embodiments of the present disclosure is inspected by the inspection method according to the embodiment of the present disclosure, electrodes of the target dummy driving transistor 3021 in the target dummy driving circuitry 302 selected from at least some of the driving circuitry columns are coupled to corresponding signal lead-out lines 40, and the signal lead-out lines 40 are coupled to corresponding test pads 41; the signals of the electrodes of the target dummy driving transistor 3021 are monitored in real time through the signal lead-out lines 40 and the test pads 41, so as to obtain the characteristics and a threshold voltage drift of the target dummy driving transistor 3021; based on the characteristics and the threshold voltage drift of the target dummy driving transistor 3021, defect analysis is performed to determine the degree of impact of the first region 10 on the target dummy driving transistor 3021; according to the determined result, a corresponding compensation scheme is implemented on the display substrate, so as to solve the problem that the characteristics of the driving transistors in the driving circuitries surrounding the first region 10 experience deviations due to the difference between the first region 10 and the second region 20, which ultimately affects the display effect of the display product.

It should be appreciated that, the expression “at a same layer” may refer to that the film layers are at a same structural layer. Alternatively, for example, the film layers at a same layer may be a layer structure which is formed through forming a film layer for forming specific patterns in a single-film-forming process and then patterning the film layer with a same mask in a single patterning process. Depending on different specific patterns, a single patterning process may include multiple exposure, development or etching processes, and the specific patterns in the formed layer structure may be continuous or discontinuous. These specific patterns may also be at different heights or have different thicknesses.

In the method embodiments of the present disclosure, the order of the steps is not limited by the serial numbers of the steps. For a person skilled in the art, any change in the order of the steps, without creative efforts, shall also fall within the scope of the present disclosure.

It needs to be noted that various embodiments in the specification are described in a progressive manner. For the same or similar parts between the embodiments, reference may be made to each other. In each embodiment, a part that is different from other embodiments is mainly described. In particular, with respect to the method embodiment, since it is substantially similar to the product embodiment, brief description is given. For the related parts, reference may be made to the description of the parts in the product embodiment.

Unless otherwise defined, the technical terms and scientific terms used in the present disclosure have the same meaning as how they are generally understood by those of ordinary skill in the art to which the present disclosure pertains. Terms such as “first” and “second” used in the present disclosure are only used to distinguish different components and are not intended to indicate any order, number or importance. Similar terms such as “comprise” or “include” mean that an element or object in front of the term covers elements or objects listed behind the term but do not exclude other elements or objects. Terms such as “connection”, “coupling”, and “connected” are not limited to a physical or mechanical connection, and may include an electrical connection, which may be a direct electrical connection or an indirect electrical connection. “Up”, “down”, “left”, “right”, and the like are only used to represent a relative location relationship. The relative location relationship may be correspondingly changed after the absolute locations of described objects are changed.

It may be understood that when an element such as a layer, a film, an area or a substrate is referred to as being “on” or “under” another element, the element may be “directly” located “on” or “under” the another element or there may be an intervening element.

In the description of the foregoing implementation, specific features, structures, materials or characteristics may be combined in an appropriate manner in any one or more embodiments or examples.

The foregoing descriptions are merely specific implementations of the present disclosure, and are not intended to limit the scope of the present disclosure. Any variation or replacement that may readily occur to a person skilled in the art within the technical scope disclosed in the present disclosure shall fall within the scope of the present disclosure. Therefore, the scope of the present disclosure shall be defined by the scope of the claims.

1. A display substrate, comprising:
a base substrate comprising a first region and a second region; wherein the second region comprises a plurality of driving circuitries, the plurality of driving circuitries comprise a plurality of normal driving circuitries and a plurality of dummy driving circuitries; each of the normal driving circuitries comprises a normal driving transistor, each of the dummy driving circuitries comprises a dummy driving transistor, and some of the normal driving circuitries are for driving an anode pattern in the first region; and the plurality of driving circuitries are divided into a plurality of driving circuitry columns, all of the driving circuitry columns surround the first region, and each of the driving circuitry columns surrounds a driving circuitry column located between the each of the driving circuitry columns and the first region;
wherein the display substrate further comprises a plurality of signal lead-out lines and a plurality of test pads, and each of the signal lead-out lines is coupled to a corresponding test pad; and
in at least some of the driving circuitry columns, at least one electrode of a target dummy driving transistor in a target dummy driving circuitry is coupled to at least one signal lead-out line.

2. The display substrate according to claim 1, wherein the plurality of driving circuitries are divided into a plurality of driving circuitry rows, each of the driving circuitry rows comprises at least one of the driving circuitries that is arranged in a first direction; and the display substrate further comprises a plurality of signal lines, at least a part of each of the signal lines extends along the first direction, and the signal lines are coupled to driving circuitries in corresponding driving circuitry rows, respectively; and
the signal line correspondingly coupled to the driving circuitry row to which the target dummy driving transistor belongs is reused as the signal lead-out line coupled to the target dummy driving transistor.

3. The display substrate according to claim 2, wherein the plurality of signal lines comprise a plurality of gate lines, a plurality of light-emitting control lines and a plurality of reset lines; each of the driving circuitry rows is coupled to a corresponding gate line, a corresponding light-emitting control line and a corresponding reset line; and
at least one of the gate line, the light-emitting control line or the reset line correspondingly coupled to the driving circuitry row to which the target dummy driving transistor belongs is reused as the signal lead-out line coupled to the target dummy driving transistor.

4. The display substrate according to claim 3, wherein
the reset line correspondingly coupled to the driving circuitry row to which the target dummy driving transistor belongs is reused as the signal lead-out line coupled to a gate electrode of the target dummy driving transistor;
the gate line correspondingly coupled to the driving circuitry row to which the target dummy driving transistor belongs is reused as the signal lead-out line coupled to a first electrode of the target dummy driving transistor; and
the light-emitting control line correspondingly coupled to the driving circuitry row to which the target dummy driving transistor belongs is reused as the signal lead-out line coupled to a second electrode of the target dummy driving transistor.

5. The display substrate according to claim 4, wherein the reset line correspondingly coupled to the driving circuitry row to which the target dummy driving transistor belongs and the gate electrode of the target dummy driving transistor are formed into an integral structure;
and/or,
wherein the target dummy driving circuitry comprises a first electrically conductive connection portion, and the gate line correspondingly coupled to the driving circuitry row to which the target dummy driving transistor belongs is coupled to the first electrode of the target dummy driving transistor through the first electrically conductive connection portion; and the target dummy driving circuitry comprises a second electrically conductive connection portion, and the light-emitting control line correspondingly coupled to the driving circuitry row to which the target dummy driving transistor belongs is coupled to the second electrode of the target dummy driving transistor through the second electrically conductive connection portion.

6. (canceled)

7. (canceled)

8. The display substrate according to claim 5, wherein the display substrate comprises a first source-drain metal layer, and the first electrically conductive connection portion and/or the second electrically conductive connection portion is made of the first source-drain metal layer.

9. The display substrate according to claim 1, wherein the at least some of the driving circuitry columns comprise an odd quantity of driving circuitry columns or an even quantity of driving circuitry columns;
and/or,
wherein adjacent driving circuitry columns in the at least some of the driving circuitry columns are spaced apart by at least one other driving circuitry column, and the other driving circuitry column does not comprise the target dummy driving circuitry.

10. (canceled)

11. The display substrate according to claim 1, wherein the display substrate further comprises an active layer, a first gate insulation layer, a first gate metal layer, a second gate insulation layer, a second gate metal layer, an interlayer insulation layer and a first source-drain metal layer stacked sequentially in a direction away from the base substrate; and
the first region further comprises a compensation structure, the compensation structure is made of at least one of the active layer, the first gate insulation layer, the first gate metal layer, the second gate insulation layer, the second gate metal layer, the interlayer insulation layer or the first source-drain metal layer.

12. The display substrate according to claim 11, wherein the compensation structure comprises compensation patterns uniformly distributed throughout the first region;
and/or,
wherein the first region comprises a plurality of anode patterns, the compensation structure comprises a plurality of first compensation patterns and a plurality of second compensation patterns; an orthogonal projection of the first compensation pattern onto the base substrate at least partially overlaps an orthogonal projection of a corresponding anode pattern onto the base substrate, an orthogonal projection of the second compensation pattern onto the base substrate at least partially overlaps an orthogonal projection of a corresponding anode pattern onto the base substrate; and the first compensation patterns are arranged at a layer different from the second compensation patterns;
and/or,
wherein the compensation structure comprises a plurality of compensation driving circuitries, and a circuit structure of each of the compensation driving circuitries is the same as a circuit structure of the dummy driving circuitry or a circuit structure of the normal driving circuitry.

13. (canceled)

14. The display substrate according to claim 12, wherein the first compensation pattern comprises a plurality of independent sub-compensation patterns, and an orthogonal projection of the sub-compensation pattern onto the base substrate at least partially overlaps the orthogonal projection of the corresponding anode pattern onto the base substrate.

15. The display substrate according to claim 14, wherein the second compensation pattern comprises a plurality of via holes, and an orthogonal projection of the via hole onto the base substrate at least partially overlaps the orthogonal projection of the corresponding anode pattern onto the base substrate.

16. The display substrate according to claim 15, wherein an orthogonal projection of the via holes in the second compensation pattern corresponding to the anode pattern onto the base substrate is covered by an orthogonal projection of the sub-compensation patterns corresponding to the anode pattern onto the base substrate.

17. The display substrate according to claim 12, wherein the first compensation patterns are made of the active layer, and the second compensation patterns are made of the interlayer insulation layer;
and/or,
wherein the plurality of anode patterns comprise a plurality of first anode patterns, a plurality of second anode patterns and a plurality of third anode patterns, and colors of sub-pixels corresponding to the first anode pattern, the second anode pattern and the third anode pattern are different; and at least two of the first anode pattern, the second anode pattern and the third anode pattern correspond to the first compensation patterns with different areas, and correspond to the second compensation patterns with different areas.

18. (canceled)

19. The display substrate according to claim 1, wherein two of the first anode pattern, the second anode pattern and the third anode pattern correspond to the first compensation patterns with a same area, and correspond to the second compensation patterns with a same area.

20. The display substrate according to claim 19, wherein the first anode pattern corresponds to a blue sub-pixel, the second anode pattern corresponds to a red sub-pixel, and the third anode pattern corresponds to a green sub-pixel; an area of the first compensation pattern corresponding to the first anode pattern is greater than an area of the first compensation pattern corresponding to the second anode pattern; and a quantity of the via holes corresponding to the first anode pattern is greater than a quantity of the via holes corresponding to the second anode pattern.

21. The display substrate according to claim 12, wherein the compensation pattern is made of one of the active layer, the first gate insulation layer, the first gate metal layer, the second gate insulation layer, the second gate metal layer, the interlayer insulation layer and the first source-drain metal layer.

22. (canceled)

23. The display substrate according to claim 12, wherein the plurality of compensation driving circuitries are divided into at least two compensation driving circuitry columns, the at least two compensation driving circuitry columns are sequentially arranged in a nested manner, and the at least two compensation driving circuitry columns are located at an edge of the first region.

24. The display substrate according to claim 1, wherein the plurality of test pads are arranged in a bezel region of the display substrate;
and/or,
wherein the first region comprises an under-screen camera region, and the second region comprises a transition region.

25. (canceled)

26. A display device, comprising a display substrate, wherein the display substrate comprises a first region and a second region; the second region comprises a plurality of driving circuitries, the plurality of driving circuitries comprise a plurality of normal driving circuitries and a plurality of dummy driving circuitries; each of the normal driving circuitries comprises a normal driving transistor, each of the dummy driving circuitries comprises a dummy driving transistor, and some of the normal driving circuitries are for driving an anode pattern in the first region; and the plurality of driving circuitries are divided into a plurality of driving circuitry columns, all of the driving circuitry columns surround the first region, and each of the driving circuitry columns surrounds a driving circuitry column located between the each of the driving circuitry columns and the first region;
wherein the display substrate further comprises a plurality of signal lead-out lines and a plurality of test pads, and each of the signal lead-out lines is coupled to a corresponding test pad; and
in at least some of the driving circuitry columns, at least one electrode of a target dummy driving transistor in a target dummy driving circuitry is coupled to at least one signal lead-out line.

27. An inspection method for inspecting a display substrate, wherein the display substrate comprises a first region and a second region; the second region comprises a plurality of driving circuitries, the plurality of driving circuitries comprise a plurality of normal driving circuitries and a plurality of dummy driving circuitries; each of the normal driving circuitries comprises a normal driving transistor, each of the dummy driving circuitries comprises a dummy driving transistor, and some of the normal driving circuitries are for driving an anode pattern in the first region; and the plurality of driving circuitries are divided into a plurality of driving circuitry columns, all of the driving circuitry columns surround the first region, and each of the driving circuitry columns surrounds a driving circuitry column located between the each of the driving circuitry columns and the first region;
wherein the display substrate further comprises a plurality of signal lead-out lines and a plurality of test pads, and each of the signal lead-out lines is coupled to a corresponding test pad; and
in at least some of the driving circuitry columns, at least one electrode of a target dummy driving transistor in a target dummy driving circuitry is coupled to at least one signal lead-out line;
wherein the method comprises:
inputting corresponding test signals to the test pads in the display substrate;
obtaining signals of electrodes of the target dummy driving transistor in the target dummy driving circuitry through the test pads;
determining a characteristic of the target dummy driving transistor in accordance with the obtained signals; and
adjusting a layout of a compensation structure in the display substrate in accordance with the characteristic of the target dummy driving transistor.
